(19) United States
(12) Patent Application Publication
(10) Pub. No.: US 2024/0178761 A1
(43) Pub. Date: May 30, 2024

(54) INTEGRATED ELECTRICAL INVERTER PLATFORM

(71) Applicant: Rosendin Electric, Inc., San Jose, CA (US)

(72) Inventors: William Paul Mazzetti, San Francisco, CA (US); Steve Emert, Menlo Park, CA (US); Shane Trese, Palo Alto, CA (US); James Crisafulli, Rosenberg, TX (US); Steve Eichelberger, Bay City, TX (US); Richard Joseph Hackley, Sugar Land, TX (US); Shawn Hanff, Longmont, CO (US)

(21) Appl. No.: 18/435,706

(22) Filed: Feb. 7, 2024

Related U.S. Application Data
(63) Continuation-in-part of application No. 17/721,030, filed on Apr. 14, 2022.
(60) Provisional application No. 63/444,170, filed on Feb. 8, 2023.
(60) Provisional application No. 63/182,496, filed on Apr. 30, 2021.

(51) Int. Cl. H02M 7/00; H05K 5/02

(52) U.S. Cl. CPC H02M 7/003; H05K 5/0247

(57) ABSTRACT

An integrated platform has an electrical inverter to convert received DC power to AC power for the electrical grid system. An electrical inverter, electrical disconnects, and electrical panels and/or cabinet enclosures are all mounted onto the integrated platform. Electrical wiring interconnecting the electrical inverter, the set of electrical disconnects, and the two or more electrical panels and/or cabinet enclosures is electrically connected up in accordance with a national electric standard in a facility. The skeletal framework, the electrical wiring, and the two or more electrical panels and/or cabinet enclosures are fabricated and received their respective electrical certifications in the facility prior to being shipped and installed. The skeletal framework supports the weight of the electrical inverter, the set of electrical disconnects, the electrical wiring, and the two or more electrical panels to allow the integrated platform to be installed into the construction site as the integrated platform.

### RELATED APPLICATIONS

This application claims priority to and the benefit of under 35 USC 119 of U.S. provisional patent application titled “VARIOUS METHODS AND APPARATUSES FOR AN INTEGRATED ELECTRICAL INVERTER PLATFORM AND A CABLE MANAGEMENT TREE,” filed Feb. 8, 2023, Ser. No. 63/444,170, which is incorporated herein in its entirety by reference. This application also claims priority under 35 USC 120 as a continuation-in-part application to U.S. non-provisional patent application Ser. No. 17/721,030, titled, “CABLE PULLING RIG SYSTEM,” filed Apr. 14, 2022, which claims priority under 35 USC 119 to U.S. provisional patent application Ser. No. 63/182,496, titled “SOLAR ARRAY POWER CABLE PULLING RIG,” filed Apr. 30, 2021, which the disclosure of such is incorporated herein by reference in its entirety.

### FIELD

Embodiments of this disclosure generally relate to an integrated electrical inverter platform.

### BACKGROUND

Saving time on construction projects is an important factor.

### SUMMARY

Provided herein are some embodiments. In an embodiment, a monolithic, pre-wired, pre-engineered, and pre-assembled integrated platform has an electrical inverter to convert received DC power to then supply AC power to an electrical grid system. The monolithic, pre-wired, pre-engineered, and pre-assembled integrated platform also has a skeletal framework that acts as an equipment support structure for an electrical inverter, a set of electrical disconnects, and two or more electrical panels and/or cabinet enclosures, which are all mounted onto the monolithic, pre-wired, pre-engineered, and pre-assembled integrated platform. A weight of the electrical inverter, the set of electrical disconnects, and the two or more electrical panels and/or cabinet enclosures is supported by the skeletal framework. Electrical wiring interconnecting the electrical inverter, the set of electrical disconnects, and the two or more electrical panels and/or cabinet enclosures is electrically connected up in accordance with a national electric standard in a facility. The skeletal framework, the electrical wiring, and the two or more electrical panels and/or cabinet enclosures are fabricated and received their respective electrical certifications in the facility as the monolithic, pre-wired, pre-engineered, and pre-assembled integrated platform prior to being shipped and installed on a construction site. The skeletal framework supports the weight of the electrical inverter, the set of electrical disconnects, the electrical wiring, and the two or more electrical panels to allow the monolithic, pre-wired, pre-engineered, and pre-assembled integrated platform to be installed into the construction site as the monolithic, pre-wired, and pre-assembled integrated platform.

These and other features of the design provided herein can be better understood with reference to the drawings, description, and claims, all of which form the disclosure of this patent application.

### BRIEF DESCRIPTION OF THE DRAWINGS

The Figures below show example embodiments of aspects of this design.

FIG. 1 illustrates a diagram of an embodiment of a monolithic, pre-wired, pre-engineered, and pre-assembled integrated platform for an electrical inverter to supply AC power to the electrical grid system that is scalable and modular.

FIG. 2 illustrates a diagram of an embodiment of two or more electrical panels and/or cabinet enclosures that can be mounted onto a floor and/or struts and/or beams of the skeletal framework.

FIG. 3 illustrates a side view of an embodiment of the skeletal framework supporting the weight of the electrical inverter, the set of electrical disconnects, the two or more electrical panels and/or cabinet enclosures, the cable routing support systems, the electrical transformer, and other equipment in order to allow the monolithic, pre-wired, pre-engineered, and pre-assembled integrated platform to be installed into the construction site as the monolithic, pre-wired, and pre-assembled integrated platform.

FIG. 4 illustrates a bottom side view of an embodiment of the electrical inverter that has structural steel added to the bottom of it.

FIG. 5 illustrates a back side view of an embodiment of the skeletal framework can be raised off the ground with a set of legs.

FIG. 6 illustrates a perspective view of an embodiment of the electrical platform comes pre-manufactured and fabricated with the electrical cabinets, the electrical inverter and its associated electrical equipment, and all their internal wiring and internal connections connecting the electrical cabinets, electrical panels, and the electrical inverter on that skid to each other already connected.

FIG. 7 illustrates a block diagram of an embodiment of one or more cable management trees configured to be installed in a solar array field to maintain an organization of multiple cables associated with solar arrays in the solar array field when pulled at the same time and then connected up to an electrical inverter, where each cable management tree is configured to be installed and then at least one of i) have the cable pulled over and ii) have the pulled alongside the cable management tree and then put into a corresponding cable clip to maintain a relative position of the pulled cables with respect to each other.

FIG. 8 illustrates a diagram of an example of a delivery vehicle with multiple cable reels, where each of the cable reels feeds a cable to a wire guide and management jig through the holes of the wire guide and management jig.

FIG. 9 illustrates a diagram of the cable-pulling-rig-system can including a wire guide and management jig mounted on first vehicle (e.g., an earth mover, a bulldozer, a forklift, a tractor, etc.) cooperating with a cable pulling jig mounted on a second vehicle.

FIG. 10 illustrates a diagram of an example tail/trailing portion of the multiple cables resting on top of the vertical support posts as the second vehicle with the cable pulling jig has already pulled the multiple cables to a location later down from the cables being shown.

FIG. 11A illustrates a front view of an example cable management tree having its set of cable clips, where each has its own identifier number/marker plate to maintain cable logistics of an identity of each cable being pulled as well as to maintain each separate cable's orientation relative to another cable being pulled at the same time, which helps to prevent the multiple cables from i) tangling ii) getting out of alignment, and iii) any combination of both, while being pulled.

FIG. 11B illustrates a side view of an example cable management tree having its set of cable clips.

FIG. 11C illustrates a perspective view of an example cable management tree with its set of cable clips.

FIG. 12 illustrates an example computing device that can be implemented in one or more components discussed herein.

While the design is subject to various modifications and alternative forms, specific embodiments thereof have been shown by way of example in the drawings and will herein be described in detail. The design should be understood to not be limited to the particular forms disclosed, but on the contrary, the intention is to cover all modifications, equivalents, and alternatives falling within the spirit and scope of the design.

### DETAILED DISCUSSION

In the following description, numerous specific details are set forth, such as examples of specific data signals, named components, number of disconnects in a platform, etc., in order to provide a thorough understanding of the present design. It will be apparent, however, to one of ordinary skill in the art that the present design can be practiced without these specific details. In other instances, well known components or methods have not been described in detail but rather in a block diagram in order to avoid unnecessarily obscuring the present design. Further, specific numeric references such as a first computing system, can be made. However, the specific numeric reference should not be interpreted as a literal sequential order but rather interpreted that the first cabinet is different than a second cabinet. Thus, the specific details set forth are merely exemplary. Also, the features implemented in one embodiment may be implemented in another embodiment where logically possible. The specific details can be varied from and still be contemplated to be within the spirit and scope of the present design. The term coupled is defined as meaning connected either directly to the component or indirectly to the component through another component.

The system for an integrated electrical inverter platform will be discussed with example embodiments. The integrated platform has an electrical inverter to convert received DC power to AC power for the electrical grid system and/or connected storage batteries. An electrical inverter, electrical disconnects, and electrical panels and/or cabinet enclosures are all mounted onto the integrated platform. Electrical wiring interconnecting the electrical inverter, the set of electrical disconnects, and the electrical panels and/or cabinet enclosures is electrically connected up in accordance with a national electric standard in a facility. The skeletal framework, the electrical wiring, and the electrical panels and/or cabinet enclosures are fabricated and received their respective electrical certifications in the facility prior to being shipped and installed. The skeletal framework supports the weight of the electrical inverter, the set of electrical disconnects, the electrical wiring, and the two or more electrical panels to allow the integrated platform to be installed into the construction site as the integrated platform.

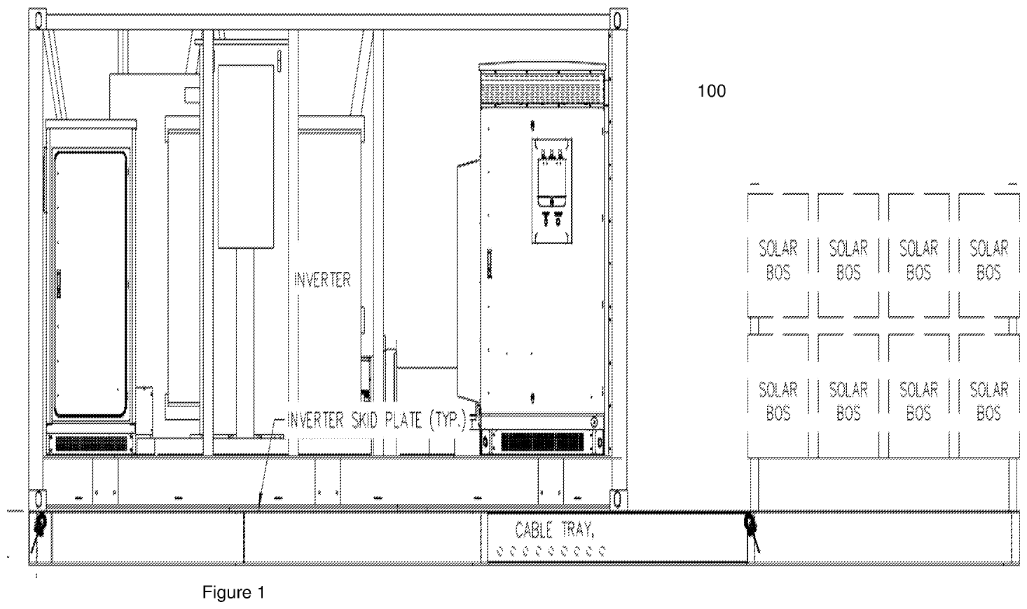

FIG. 1 illustrates a diagram of an embodiment of a monolithic, pre-wired, pre-engineered, and pre-assembled integrated platform for an electrical inverter to supply AC power to the electrical grid system that is scalable and modular. The monolithic, pre-wired, pre-engineered, and pre-assembled integrated platform 100 has an electrical inverter to convert received DC power from a DC source in order to then supply AC power to an electrical grid system. The monolithic, pre-wired, pre-engineered, and pre-assembled integrated platform 100 also has a skeletal framework that acts as an equipment support structure, an electrical inverter, and a set of electrical disconnects, an electrical transformer to couple to the electrical grid system, and other equipment. The weight of the electrical inverter, the set of electrical disconnects, the electrical transformer, the two or more electrical panels and/or cabinet enclosures, and other equipment is supported by the skeletal framework.

The skeletal framework and the cabinet enclosures are fabricated in a facility as a monolithic, pre-wired, pre-engineered, and pre-assembled integrated platform 100 prior to being shipped and installed on a construction site. The skeletal framework supports the weight of the cabinets and cable routing support systems to allow the integrated platform including its mounted cabinets, electrical inverter, etc. to be installed into a construction site as a monolithic, pre-wired, and pre-assembled integrated platform.

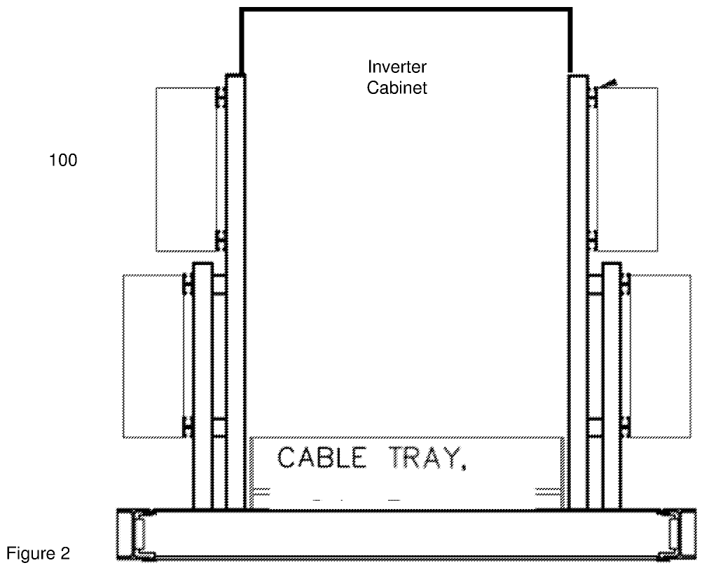

FIG. 2 illustrates a diagram of an embodiment of two or more electrical panels and/or cabinet enclosures that can be mounted onto a floor and/or struts and/or beams of the skeletal framework. One or more national electric standard approved electrical cable routing support systems are mounted onto an upper portion, a lower portion, or in both, of the skeletal framework.

The electrical inverter can be a piece of equipment in a solar energy system. The electrical inverter converts direct current (DC) electricity, which is what an array of solar panels generates, to alternating current (AC) electricity, which the electrical grid uses. The electrical inverter regulates the flow of electrical power.

The electrical inverter accomplishes the DC-to-AC conversion by switching the direction of a DC input back and forth very rapidly. As a result, a DC input becomes an AC output. In addition, filters and other electronics are used to produce a voltage that varies as a clean, repeating sine wave that can be injected into the electrical power grid. The electrical power inverter uses a stable DC power source from, for example, one or more strings of solar arrays that are capable of supplying enough current for the intended power demands supplied to the electrical power grid. The electrical inverter can supply hundreds of thousands of volts to the power transmission system.

Supervisory Control and Data Acquisition (SCADA) cabinets mounted on the skid to monitor various electrical parameters on, for example, the electrical power grid. One or more of the cabinet enclosures on the monolithic, pre-wired, pre-engineered, and pre-assembled integrated platform 100 are Supervisory Control and Data Acquisition (SCADA) control cabinets in order to allow the electrical inverter to connect and disconnect from the electrical power grid while minimizing any transient issues or other faults. Also, when the electrical power grid stops behaving as expected, like when there are deviations in voltage or frequency, the smart electrical inverter can respond in various ways. The electrical inverter can provide reactive power to the electrical grid to assist in controlling deviations in voltage or frequency via the SCADA control cabinet. The smart electrical inverter, via the SCADA control cabinet, can both provide and absorb reactive power to help grids balance this important resource.

In a large-scale utility plant or mid-scale community solar project, every solar panel might be attached to a single central electrical inverter. Alternatively, a string of solar panels may connect to its own electrical inverter. That electrical inverter converts the power produced by the entire string of solar power panels to AC voltage. The DC source is a string of two or more solar power arrays that supply current and DC voltage equal to or greater than 100,000 watts into the electrical inverter and an AC power out to the electrical grid system running at frequencies, such as 50 and 60 Hz. The electrical inverter can supply the AC power out to the electrical grid system at a set frequency, such as 50 Hz and 60 Hz, depending upon a standard AC frequency utilized by that country. An electrical transformer can couple to the electrical grid system and be mounted on the skeletal framework to isolate the electrical inverter from the electrical power grid itself. The electrical inverter might also have a system, similar to SCADA cabinets, that controls how the solar system interacts with an attached battery storage. The electrical inventor can control a charge rate into the battery and/or draw current from a charged battery to supply that power to the electric power grid.

The monolithic, pre-wired, pre-engineered, and pre-assembled integrated platform 100 can have two or more electrical inverters installed to scale up to an amount of power needed to an amount supplied to the electrical power grid by supplying enough electrical inverters. Each electrical inverter has an electrical power rating capable of supplying set amount of AC power such as one megawatt. Thus, five electrical inverters, each supplying one megawatt could supply 5 megawatts to the electrical grid. Each electrical inverter can be supplied from its own corresponding string/set of the solar arrays.

In general, disclosed herein are various methods and apparatuses associated with a pre-wired and pre-engineered integrated platform for the electrical inverter and its associated equipment to supply AC power to the electrical grid that is pre-assembled, scalable, and modular.

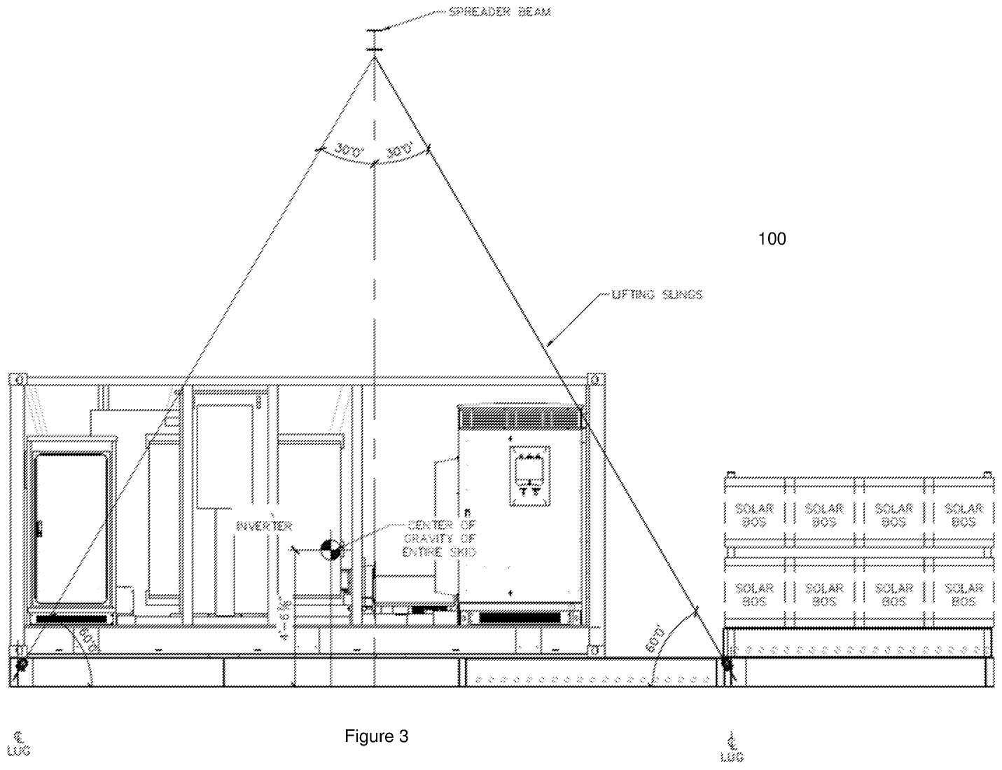

FIG. 3 illustrates a side view of an embodiment of the skeletal framework supporting the weight of the electrical inverter, the set of electrical disconnects, the two or more electrical panels and/or cabinet enclosures, the cable routing support systems, the electrical transformer, and other equipment in order to allow the monolithic, pre-wired, pre-engineered, and pre-assembled integrated platform to be installed into the construction site as the monolithic, pre-wired, and pre-assembled integrated platform. The monolithic integrated platform may be fabricated by pre-wiring, pre-engineering and assembling the integrated platform with the electrical inverter and its associated equipment. The fabricated the skeletal framework supporting the mounted cabinet enclosures, the electrical inverter and its associated equipment, which are wired and assembled in a factory/facility setting may then be installed in the construction site as a monolithic, pre-wired, and pre-assembled integrated platform. The monolithic, pre-wired, pre-engineered, and pre-assembled integrated platform 100 is constructed to put (e.g., locate) the heavy weights of the cabinets and other equipment such that a center of gravity is essentially through a center of the platform in order to allow easy and smooth lifting when the monolithic, pre-wired, pre-engineered, and pre-assembled integrated platform 100 is placed in the field. The skeletal framework itself is formed as a support structure for the integrated platform. The skeletal framework includes an upper framework and a lower framework. The two or more cabinet enclosures are mounted onto the lower framework or the sides of the framework, which includes one or more electrical disconnects in enclosures. The weight of the two or more cabinet enclosures and the inverter is supported by the skeletal framework to allow the integrated platform including its mounted cabinets to be installed into a construction site, such as a solar farm, as a monolithic, pre-wired, and pre-assembled integrated platform. In an embodiment, one or more National Electric Code approved electrical cable routing support systems are mounted onto the upper framework.

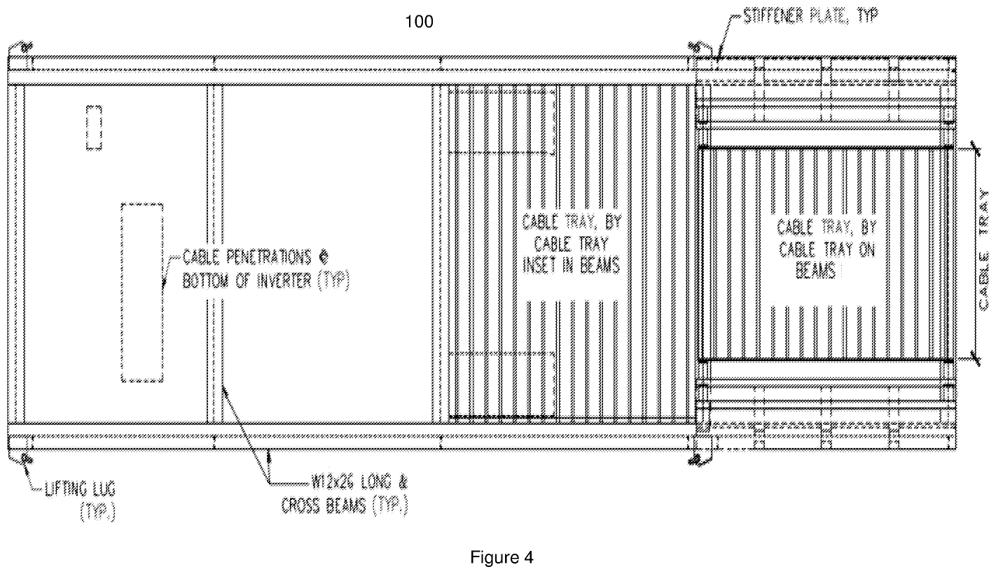

FIG. 4 illustrates a bottom side view of an embodiment of the electrical inverter that has structural steel added to the bottom of it. The monolithic, pre-wired, pre-engineered, and pre-assembled integrated platform 100 has one or more structural steel stiffener plates installed between cross beams forming the skeletal frame added to a bottom of the monolithic, pre-wired, pre-engineered, and pre-assembled integrated platform 100. The skeletal framework can also have multiple penetrations in a bottom floor and one or more sides of the monolithic, pre-wired, pre-engineered, and pre-assembled integrated platform 100 to route cables internal and external to the electrical inverter, the electrical disconnects, and the electrical panels and/or cabinet enclosures mounted on the monolithic, pre-wired, pre-engineered, and pre-assembled integrated platform 100.

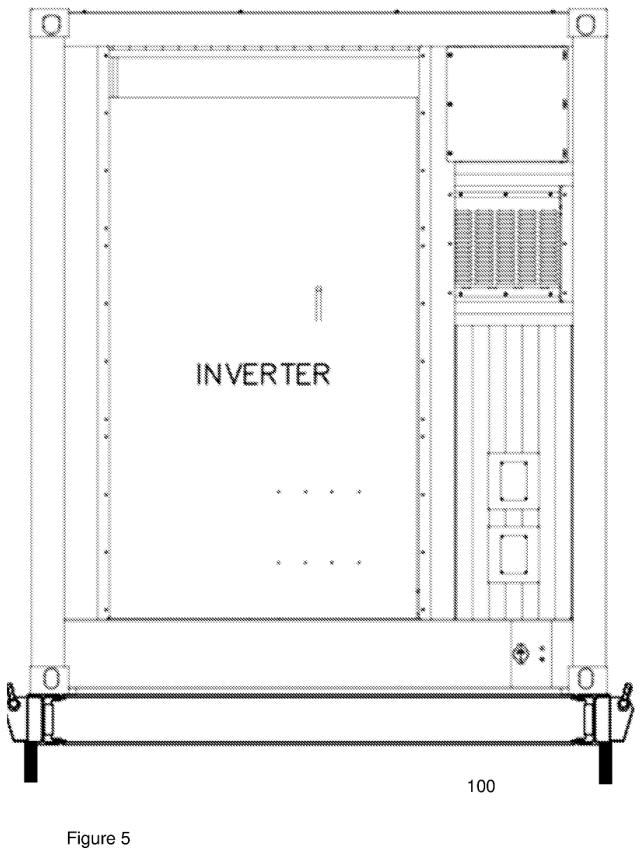

Referring back to FIG. 3, the skeletal framework has an upper section and a lower section with beams forming the skeletal framework. The horizontal beams are welded together with intersecting vertical (column) beams in order to form a monolithic structure that can be lifted and carried into place as a singular modular unit. The lower section and potentially an upper section of the skeletal framework has 1) a series of eye bolts (e.g., lugs) welded into the framework, 2) reinforced holes in one or more beams making up the skeletal frame, and/or 3) a combination of both, (also see the lugs in FIG. 5) in order to allow the monolithic, pre-wired, pre-engineered, and pre-assembled integrated platform 100 to be lifted and set into place by at least one of a crane and a chain hoist. The eye bolts are not mated to a nut and then torqued because that would not form a structurally sound enough mechanical connection for the lifting and placing the electrical platform as one modular unit. As a result, the lower framework or both the lower and upper frameworks and may have a series of eye bolts welded into the skeletal framework beams. Again, the integrated platform may be lifted and set into a place by a crane, chain hoist, or other mechanical lifting device using the eye bolts. The monolithic, pre-wired, pre-engineered, and pre-assembled integrated platform 100 with an electrical inverter can weigh with the equipment 45,000 pounds or more. The center of gravity with the equipment for a 20 foot skid would be roughly at the 10 foot section. The center of gravity of the entire system could be up to 2 and ½ foot left of the center beam location. The rigging contractor must take precaution when lifting, as the mounted equipment may make it tilt, however the center of weight with the equipment and the cabinets designed to put the most weight in the center. At least four lifting points (e.g., lugs) may be required to lift the monolithic, pre-wired, pre-engineered, and pre-assembled integrated platform 100 with the electrical inverter(s) properly in place. The platform may have at least four lugs and, in an example, ten lugs (one at each opposing corner and two in the middle of the platform) are welded into the frame. The lifting lugs are heavy duty lifting lugs such as lugs with a 17 ton weight capacity or greater per shackle. The lifting procedure may require a test lift to lift the monolithic, pre-wired, pre-engineered, and pre-assembled integrated platform 100 several inches (e.g., 6 to 8 inches) in the air and check out the integrated platform for any deformation or any center of gravity issues prior to attempting to set the monolithic, pre-wired, pre-engineered, and pre-assembled integrated platform 100 in place in the field. The monolithic, pre-wired, pre-engineered, and pre-assembled integrated platform 100 may also have struts and/or holes in the skeletal frame to allow connection to tag lines to control swaying and spinning of the monolithic, pre-wired, pre-engineered, and pre-assembled integrated platform 100 in place when installing the platform in the field.

FIG. 5 illustrates a back side view of an embodiment of the skeletal framework can be raised off the ground with a set of legs. The skeletal framework has a set of legs under a metal floor of the skeletal framework to raise a remainder of the monolithic, pre-wired, pre-engineered, and pre-assembled integrated platform 100 with the electrical inverter off the ground with the set of legs. The set of legs can include one leg at each corner of the integrated platform and then at least one leg per side in a middle of the integrated platform to support the weight of the integrated platform. The skeletal framework can also have one or more cable trays built in. The skeletal framework, the electrical inverter, the set of electrical disconnects, the electrical transformer, the two or more electrical panels and/or cabinet enclosures, and the cable trays are weatherproofed for outdoors use. The weatherproofing includes the skeletal framework being galvanized and/or having another corrosion prevention treatment.

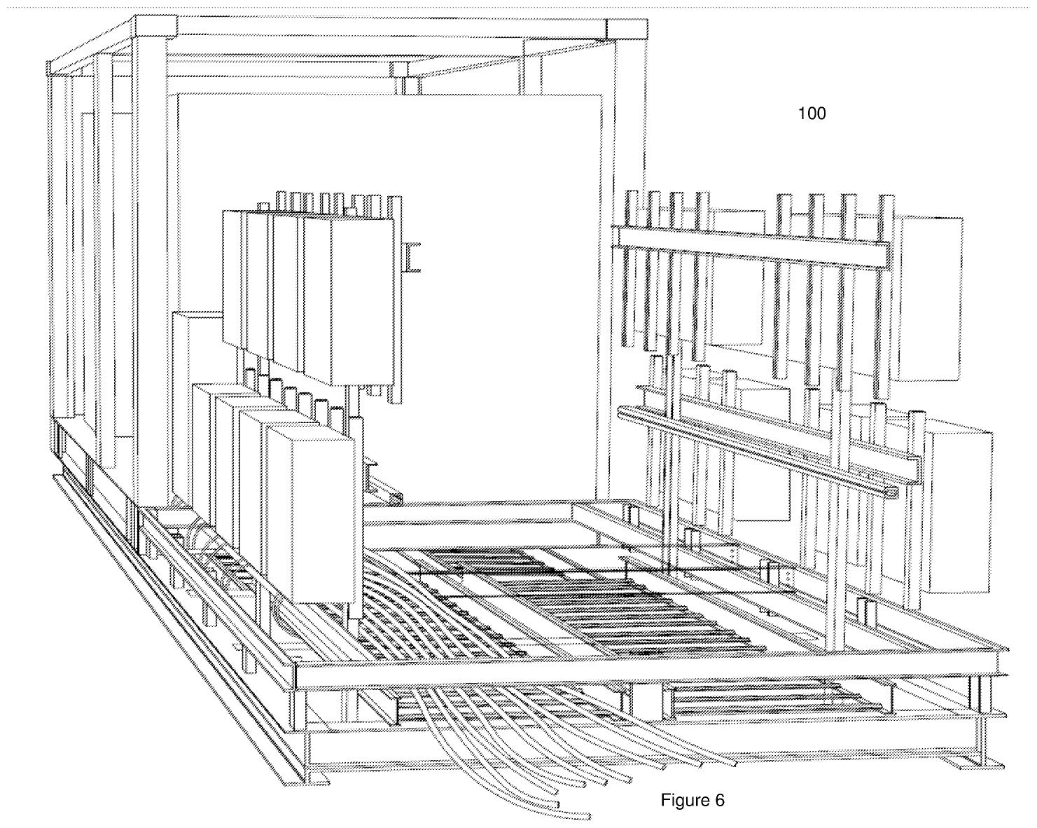

FIG. 6 illustrates a perspective view of an embodiment of the electrical platform comes pre-manufactured and fabricated with the electrical cabinets, the electrical inverter and its associated electrical equipment, and all their internal wiring and internal connections connecting the electrical cabinets, electrical panels, and the electrical inverter on that skid to each other already connected. The electrical wiring interconnecting the electrical inverter, the set of electrical disconnects, the electrical transformer, the two or more electrical panels and/or cabinet enclosures, and other equipment are electrically connected up in accordance with a national electric standard (such as the NEC) in a facility. The skeletal framework, the electrical connections, and the cabinet enclosures are fabricated and received their respective electrical certifications in the facility as the monolithic, pre-wired, pre-engineered, and pre-assembled integrated platform 100 prior to being shipped and installed on a construction site.

As discussed, the cabinets and the one or more electrical inverters can be mounted securely in place on the beams of the lower section making up essentially the floor of the platform. The electrical panels and cabinets can use pre-terminated whips with camlock connectors on the end. The set of electrical panels and/or cabinet enclosures can use pre-terminated whips with male plug connectors or female receptacle electrical connectors. The set of electrical panels can be mounted in a bulkhead on a structural member of the skeletal framework. The cam lock connectors (e.g., electrical male end plugs and corresponding female end receptacles) can be installed so that a worker can merely plug the solar array power and electrical equipment on the platform together when the inverter platform is installed in place. A wall of electrical disconnects can be mounted on structural steel of the skeletal frame. Accordingly, the integrated platform allows for a turnkey installation of the electrical inverter, its disconnects, electrical cabinets, control system, and associated wiring/cabling to happen in the factory and be installed as a modular unit allowing for a rapid deployment of this platform to occur on a construction site. The skid with its installed inverter, cabinets, disconnects, etc., does not need to assemble the cabinets, inverter and panels and their corresponding connecting wiring internal to the skid at the construction site and then test those connections and electrical components. This all happens at the factory while construction is occurring at that site. All of those activities as well as additional installation of breaker panels, AC voltage outlets, lighting, low-voltage distribution panels and so forth can be installed on the platform and tested prior to shipping the modular unit to the site where construction is occurring. Thus, the integrated platform with the electrical inverter is designed, assembled, internally wired, and tested out, all prior to being shipped to the construction site and comes in as a modular integrated solution for an electrical inverter capable of connecting to the electrical grid at that site. The integrated platform with the electrical inverter and all of the electrical equipment and wiring can be inspected and certified at the factory; and thus, pre-commissioned and ready to go as an assembled electrical power grid ready inverter on the skid.

Next, then bring you bring your feeder cables from the DC source, such as the string of solar arrays, in from the field and terminate them into the one or more electrical disconnect switches mounted on the structural steel on the integrated platform.

Next, the electrical inverter cooperates with a set of cable management trees installed in a solar array field to maintain an organization of cabling coming from each of the solar arrays when pulled and then connected up to the electrical inverter, via one or more electrical disconnects, on the monolithic, pre-wired, pre-engineered, and pre-assembled integrated platform 100.

The cable management tree may be used by itself and/or in conjunction with the integrated inverter platform to replace prior cable management system, such a snake tray. The cable management tree can be used for cable wire management.

The monolithic, pre-wired, pre-engineered, and pre-assembled integrated platform 100 with the electrical inverter can be placed/located in between the North and South tables of a solar power farm. There is a gap within both the North and South Table. Cabling from the solar arrays can be pulled and then connected up to the electrical inverters, via the electrical disconnects, on the inverter platform. The pulled cable can be routed through and supported by instances of the cable management tree. Each instance of the cable management tree may be installed at set distances from each other. The design can remove the gaps within the North and South table, and instead have a single trunk line down the center between those two tables.

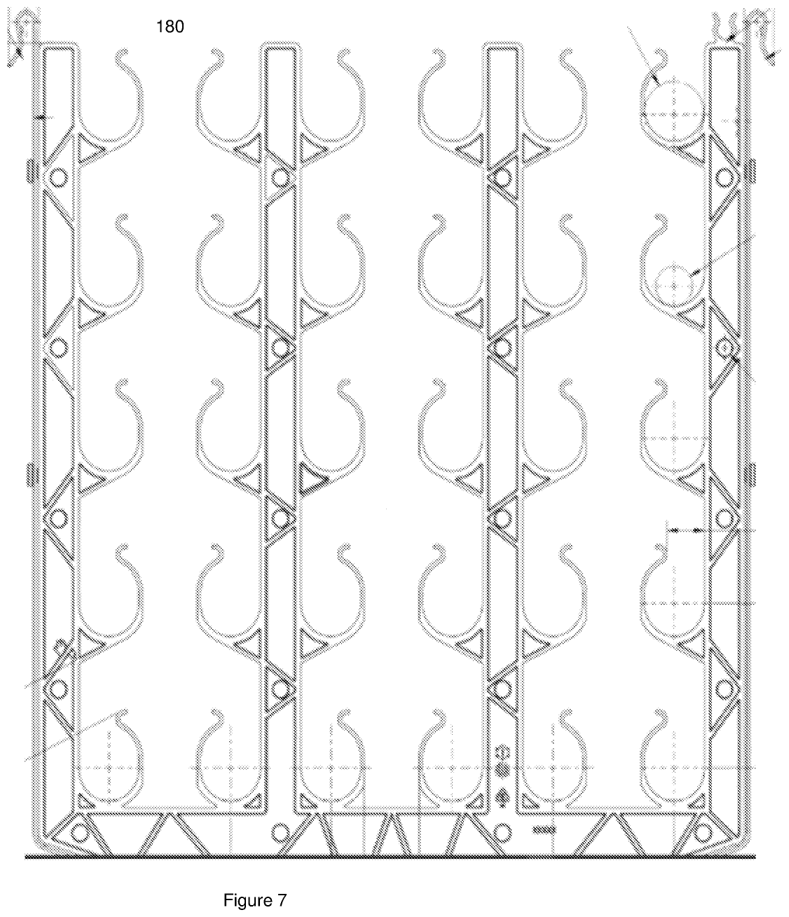

FIG. 7 illustrates a block diagram of an embodiment of one or more cable management trees configured to be installed in a solar array field to maintain an organization of multiple cables associated with solar arrays in the solar array field when pulled at the same time and then connected up to an electrical inverter, where each cable management tree is configured to be installed and then at least one of i) have the cable pulled over and ii) have the pulled alongside the cable management tree and then put into a corresponding cable clip to maintain a relative position of the pulled cables with respect to each other. The cable management tree has two or more individual support stanchion posts, and each support stanchion post has its own set of cable clips to hold a cable. The cable management tree has three or more support stanchions, each support stanchion with its own set of cable clips, where at least two of the support stanchions also form part of a frame of the cable management tree. The cable management tree has two or more support stanchions that arise out of a middle of the cable management tree, where each of those two or more support stanchions has a set of cable clips on both sides of the support stanchion.

Note, the cable pulling occurs with multiple cables being pulled at the same time with heavy equipment through the cable management tree. For example, 15 feeders or 30 conductors can be pulled by the tractor, front end loader, etc. at the same time where each is pulled over the cable management tree and put into corresponding cable clips to maintain the relative positions of the pulled cables with respect to each other. Each different cable connects to different strings in the solar array and/or different electrical points making up the DC circuit in the solar array farm. As these cables are pulled, then they would move and be jostled in a manner to lose the ability to keep track of an identity of cable, without the benefit of the cable management tree and other components herein utilized to maintain the organization of the cables; and thus, which cable is coming from what point in the DC circuit making up the solar array farm.

The cable management tree can be just a single piece of molded plastic with multiple support stanchions forming columns of cable clips, where each clip is configured to receive a corresponding cable of the multiple cables being pulled at the same time. In this example, the cable management tree has six columns of cable clips attached to four support stanchions to receive feeder cables. A metal piece/strip is designed to go around inside or on an outside of a frame of the cable management tree as well as each support stanchion in the interior of the cable management tree has a metal strip to structurally support a weight of that structure and the corresponding cables being held in each cable clip. The cable management tree has two or more individual support stanchion posts, and each one has its own set of cable clips to hold cables. In the example, the cable management tree acts as a cable guide and has two center support stanchions and two other support stanchions forming the exterior walls/sides with a tree architecture, so that you can route the feeder cables into the hook shaped cable clips on each of the support stanchions. Again, the cable management tree is designed to maintain the relative positioning of multiple cables being pulled at the same time. The cable management tree is configured to act as a cable guide to maintain the relative positioning of multiple cables being pulled at the same time, where each of the cable clips has at least one of i) an identifying number and ii) a unique code so that a particular cable being routed through that cable clip can be easily tracked. The cables are pulled and set over and/or alongside the cable management tree. Next, the cable is pulled and placed into a cable clip. The example cable management tree has its own set of cable clips to hold its corresponding cable to maintain cable logistics of an identity of each cable being pulled as well as to maintain each separate cable's orientation relative to another cable being pulled at the same time, which helps to prevent the multiple cables from i) tangling ii) getting out of alignment, and iii) any combination of both, while being pulled. Thus, multiple cables are pulled down a row of solar arrays and can be installed into their respective cable management trees along the way.

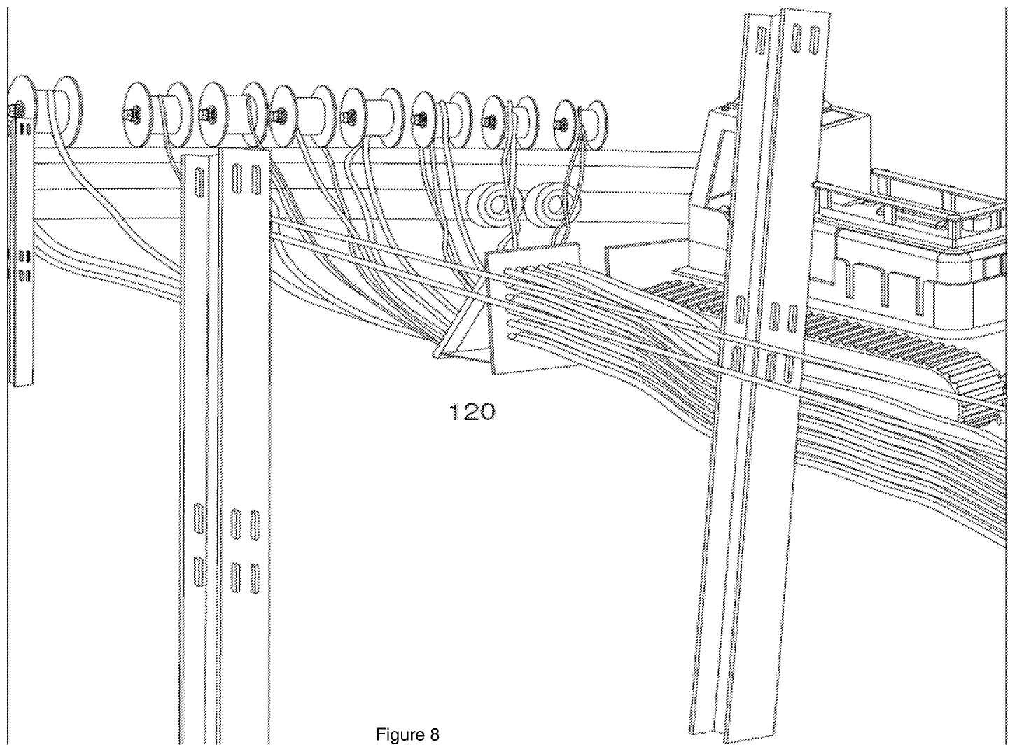

FIG. 8 illustrates a diagram of an example of a delivery vehicle with multiple cable reels, where each of the cable reels feeds a cable to a wire guide and management jig through the holes of the wire guide and management jig. As shown, the wire guide and management jig 120 is attached through its mechanical coupling to an arm, such as a fork, of a forklift. The cable pulling system can include the cable pulling jig 140. The cable pulling jig 140 is constructed to draw the multiple cables off a delivery vehicle (e.g., a flatbed trailer), where the multiple cables each on its own cable reel are located. The reels of cable on a bed of a delivery vehicle are positioned so that the middle, front facing cable reels of cable for the longer feeder cable pulls are directly perpendicular with the cable tray. The cable reels of cable near the front and the back will be angled toward the cable tray, allowing all the feeder cables to be pulled into the cable tray. While the cable-pulling-rig-system is equipment-mounted, one or more workers can draw/pull cable from cable reel on a flatbed trailer-mounted cable management tree 180 that feeds cable to the cable pulling jig 140. This delivery vehicle (e.g., trailer truck) based system holds several large reels of cable for the installation, and this trailer-based cable reel spooling system assists the cable-pulling-rig-system to achieving the productivity goals that have been set. In an example, the cable-pulling-rig-system pulls the wire/cables off a truck through the one or more jigs, such as the wire guide and management jig 120, until the crew is finished pulling each of the cables being through holes in the jig. The cables can be temporarily coupled to the cable pulling jig 140. The cable pulling jig 140 couples to a vehicle which then drives the cable pulling jig 140 and the attached cables being pulled off their reels to a desired location, such as a cable tray, while the cable pulling jig 140 and the attached cables are cantilevered over top of a cable tray. The cable pulling jig 140 is constructed to draw the multiple cables off a delivery vehicle through the wire guide and management jig 120 to guide each pulled cable into a job site's desired set of one or more cable management trees 180. The cable pulling jig 140 is configured to draw the multiple cables off cable reels through the wire guide and management jig 120, and then the cable pulling jig 140 is configured to temporarily attach to the multiple cables when they are pulled through the wire guide and management jig 120 to a desired location. The wire guide and management jig 120 can have a set of holes in the plate that supports the weight of the multiple cables without deforming even when dragging thousands of pounds of cables. Again, the plate can be made from one inch to two inch thick steel. The set of holes in the plate also spaces out the multiple cables such that they can easily go into a wire guide and management jig 120.

Thus, the cable-pulling-rig-system can include a cable pulling jig, rows of cable management trees, one or more vehicles to couple to the cable pulling jig to pull multiple cables and the cable management tree, and other components. The wire guide and management jig attached to a vehicle is constructed to help manage the multiple cables to prevent the multiple cables from i) tangling ii) getting out of alignment, and iii) any combination of both, while being pulled. The set of cable management trees deployed on the ground are configured to cooperate with the one or more vehicles pulling these cables. The one or more vehicles, such as an earthmover, a forklift, a bulldozer, a tractor, and any combination of these, that are configured to act as i) an energy source, ii) a stabilizing platform with sufficient weight to pull the multiple cables, and iii) a movement source with off-road traction during the pulling of the multiple cables from cable reels to a target destination in the solar array field. Multiple cables can be pulled at a same time and then select the proper instance of cable management tree to hold and maintain the organization the cables being pulled long term. The cable management trees deployed on the ground can come in standard instances that have a tree architecture with different amounts of cable clips, to each hold its own cable, such as 8 cable feeders, 15 cable feeders, 18 cable feeders, 30 cable feeders or 36 cable feeders.

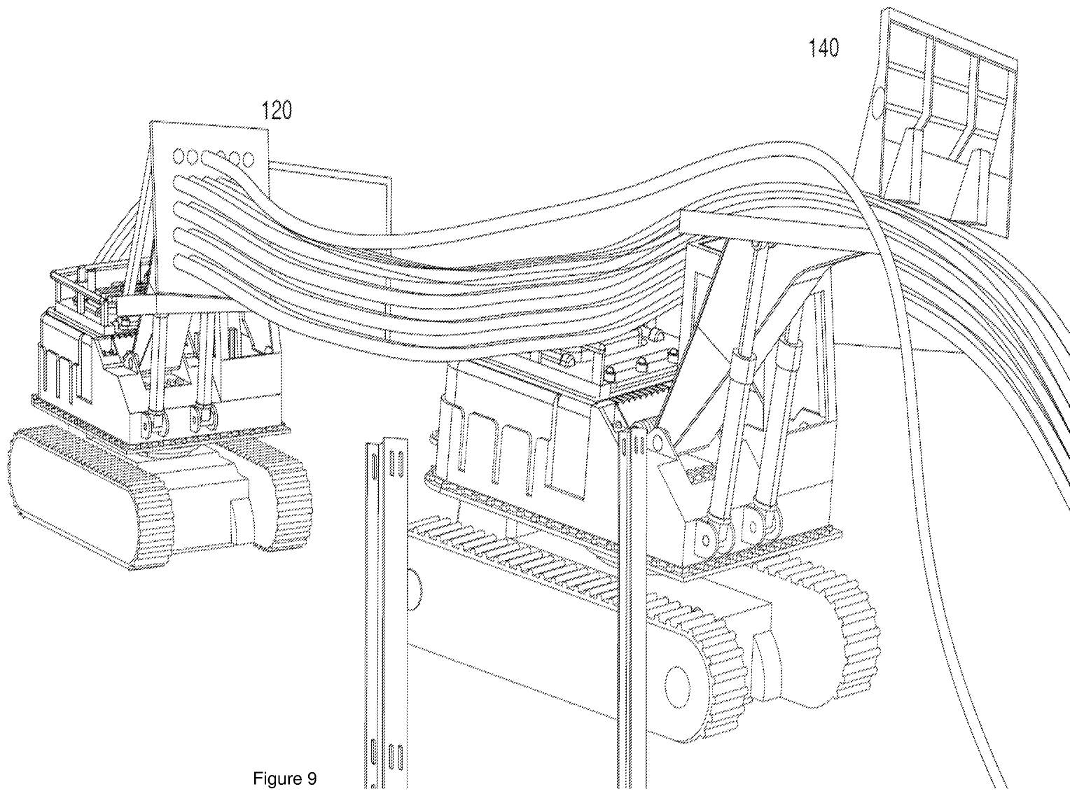

FIG. 9 illustrates a diagram of the cable-pulling-rig-system can including a wire guide and management jig mounted on first vehicle (e.g., an earth mover, a bulldozer, a forklift, a tractor, etc.) cooperating with a cable pulling jig mounted on a second vehicle. The cable-pulling-rig-system can be a two-part system. One part of the cable-pulling-rig-system is cable pulling with a cable pulling jig 140 and the second vehicle, while another part of the cable-pulling-rig-system is cable management with a wire guide and management jig 120 with the first vehicle, a set of cable management trees deployed on the ground 180, and optionally and vertical cable support posts 160 (e.g., PVC tubes in a shape of a goal post). The combination of the two parts is to draw cable off the cable reels on a delivery vehicle (e.g., a flatbed trailer) (see FIG. 9 for example) in which the cable reels are located through the wire guide and management jig 120 to guide the pulled cable into that site's desired one or more cable management trees 180 to form an above ground cable tray. As discussed, the cable pulling system can include multiple reels of cable, a cable pulling jig 140, and an example vehicle, such as an earthmover, as the main energy source to pull the cables, the wire guide and management, the set of cable management trees, and other components. The wire pulling crew routes and sets the cables into the wire guide and management jig 120 and hooks them onto the cable pulling jig 140, which is then pulled into/over the set of cable management trees 180. This then allows the cable pulling crew to lay cable directly into the one or more instances of the wire guide and management jig 120. The example vehicle (e.g., forklift) can lift its arms (e.g., forks) and use a mechanical coupling (e.g., sleeve retention) fabricated into the arms to support the wire guide and management jig on one side and the counterweight on the other side as well as the multiple cables being pulled. Each cable of the multiple cables individually goes through a corresponding hole in a matrix of holes formed in a plate of the rectangular wire guide and management jig when the arm of the vehicle has raised the wire guide and management jig and its multiple cables into the air. The cable-pulling-rig-system can be specifically designed to pull cable in a site's exposed set of cable management trees 180, which is an exposed cable management structure. In an embodiment, the cable-pulling-rig-system can be used to pull power cables for a solar power farm consisting of rows of solar arrays and their trackers.

An example cable pulling jig can be attached to a steel beam via a mechanical coupling (e.g., retention guide) welded to the arms (e.g., forks) of a forklift. The forklift's arms can be raised into the air during the cable pull. The cable pulling jig 140 and attached cables are being held cantilevered over the vertical support posts and/or cable management trees. The multiple cables will rest on the vertical support posts (e.g., PVC posts in a shape of a goal post) and after the cables are pulled to their eventual end location. The multiple cables were either laid inside or alongside the cable management tree 180, such as a closed cable tray or open cable tray structure. Next, the loops on the end of the cables can be unhooked from the hooks of the cable pulling jig 140.

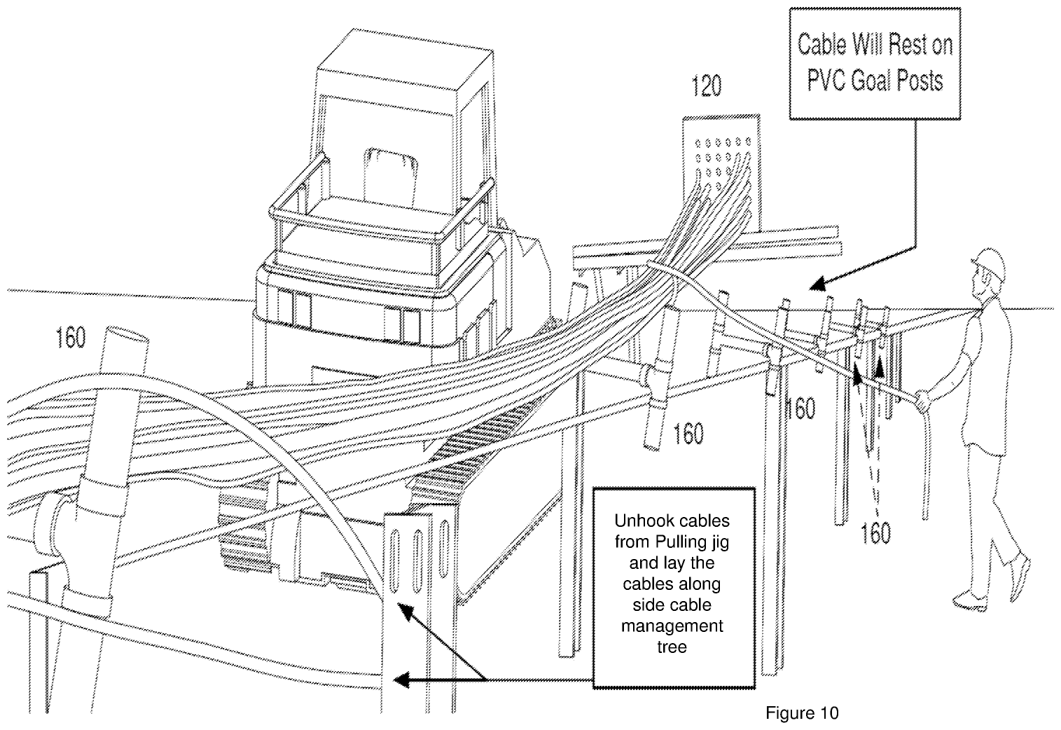

FIG. 10 illustrates a diagram of an example tail/trailing portion of the multiple cables resting on top of the vertical support posts as the second vehicle with the cable pulling jig has already pulled the multiple cables to a location later down from the cables being shown. The multiple cables can be cut or still attached to the cable reel. The multiple cables lay and rest above the ground on vertical support posts of the cable tray during the pulling of the cables. In addition, the vertical cable support posts 160 are constructed to support a weight of the multiple cables and have the vertical cable support posts 160 rest on the vertical cable support posts 160 (e.g., PVC goal posts) as the multiple cables are pulled by the cable pulling jig 140 coupled to the first vehicle. The vertical cable support posts 160 system of, for example, PVC tubes can help to relieve rotational and dragging forces on the plate of the wire guide and management jig 120. The cable management trees 180 can merely be used close to a destination location of where cables are going to be terminated. The cable management trees 180 can be used to replace the vertical cable support posts 160 completely.

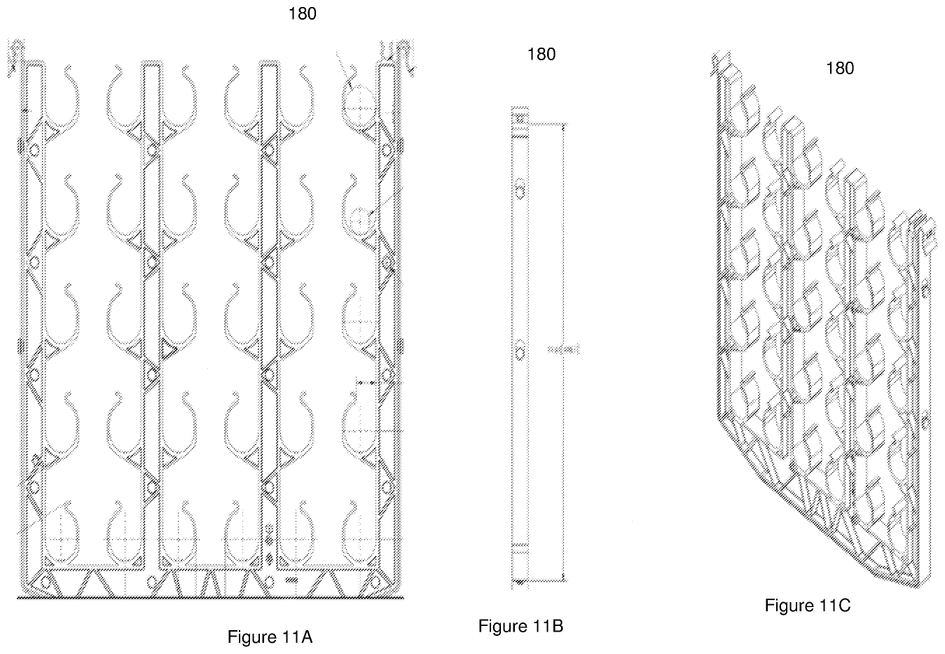

FIG. 11A illustrates a front view of an example cable management tree having its set of cable clips, where each has its own identifier number/marker plate to maintain cable logistics of an identity of each cable being pulled as well as to maintain each separate cable's orientation relative to another cable being pulled at the same time, which helps to prevent the multiple cables from i) tangling ii) getting out of alignment, and iii) any combination of both, while being pulled. FIG. 11B illustrates a side view of an example cable management tree having its set of cable clips. FIG. 11C illustrates a perspective view of an example cable management tree with its set of cable clips. The cable management tree 180 has a set of cable clips and support stanchions that support the weight of the multiple cables without deforming. The set of cable clips are spaced out such that the multiple cables can easily go into a cable management tree 180 to be used as an open cable tray structure. Note, each layer of cable is laid into its layer of the tree structure of the cable management tree 180. The cable management tree 180 has an example five rows of cable clips with four columns of cable clips. Each cable clip is made of a flexible material. The cable clip is made of a flexible material such that an entrance to the first cable clip, formed by a lip and an upper portion of a hook shape of the first cable clip, can expand to contain cables in a well of the cable clip that have a diameter greater than an opening to the entrance to the first cable clip, where a well to hold the cable is formed from an interior wall of the hook shaped cable clip and an exterior of a support stanchion. The feeder cable is held in place in the cable clip between the interior of the hook shaped cable clip and the exterior of the support stanchion for that column. The example cable management tree 180 can hold 30 individual cables in its 30 individual cable clips hanging off four support stanchions. Each cable clip has a reinforced structure at a bottom of a cable clip to help hold a weight of different cable sizes a cable being held by the cable clip, which allows a top hook portion of the cable clip to be made of a much more flexible and thinner material that will snap back into its normal position to maintain a rough nominal distance for an opening between a cable clip hook interior and a support stanchion into the first cable clip. Each cable clip can be pulled and be flexible enough to stretch out to accommodate a cable with a diameter greater in dimensions than the distance of the entrance into that cable clip. The distance of the entrance into that cable clip can be expanded between the lip of the cable clip and the wall of the support stanchion that the cable clip is attached to. Note, at least two of the support stanchions forming part of the frame of the cable management tree 180 have supporting steel to bear the weight of the frame and cables. Two example support stanchions arise out of the middle of the cable management tree 180 and two example support stanchions form a part of the outside frame of the cable management tree 180. Each of those support stanchions forming a frame has a set of cable clips on one side of the support stanchion. Each of the support stanchions in the middle have a set of cable clips on both sides of the support stanchion. Then, in this example, there are five cable clips on each side of the support stanchion in the middle of the cable tree management structure. The cable management tree 180 can have different instances/versions to accommodate different numbers of cable clips and thus feeder cables in those cable clips. The cable management tree 180 can come in standard instances that have a tree architecture with different amounts of cable clips, to each hold its own cable, such as 8 cable feeders, 15 cable feeders, 18 cable feeders, 30 cable feeders, 36 cable feeders, etc. The cable management tree 180 can have different amounts of support stanchions to increase or decrease an amount of cable clips. In addition, the spacing between rows of cable clips can be increased or decreased to change the amount of cable clips attached to a given support stanchion.

One or more cable management trees coupled in series 180 can hold the cables to form a cable tray. A set of two or more cable management trees 180 can be set closer together to form a very stable cable tray structure. The structure of the cable tray can be rectangular to form a very stable structure. Thus, a series of cable management trees are configured to be installed at set distances from each other such that two or more cable management trees hold and contain a same set of cables. The cable management tree open architectural design allows the cables to be securely managed while allowing for proper airflow so cables can operate at full amperage capacity and be derated. The molded structure of the tree architecture can be used to maintain a delineation between rows of cables laid into its corresponding row of the tree structure.

Advantageously, one need not take the manhours/time needed to build a cable management system up from the ground, column and row after column and row. Rather the structured cable management tree on its own support stanchions with a tree architecture can easily be installed in the ground and save a large amount of installation time.

Referring back to FIG. 10, the cable logistics and pre-pulling material configuration are important to the success of the cable-pulling-rig-system and the specific installation motion it supports. A cable can be first cut to length and spooled according to pull or pulled and then cut. The cable-pulling-rig-system replaces several people with one or more vehicles coupled (e.g., welded to forklift) to the cable pulling jig 140 to pull the cable and the wire guide and management jig 120 to manage the organization of the cables as they are pulled. The cable-pulling-rig-system minimizes a need for people to handle or physically pull cable from the cable reel when compared to current practices. Once the vehicle pulling the cables reaches its target destination (e.g., the last row of a disconnect or other electrical connection), the crew can unhook the prefabricated eyelets on the cables from the cable pulling jig 140 and lay each cable along the side of the set of one or more cable management trees 180. The crew can continue this process until the remainder of the feeder cables are pulled out and laid next to the set of one or more cable management trees 180. Next, the crew can disconnect any remaining feeder cables from the cable pulling jig 140 and stage the vehicle (e.g., bulldozer) at the next block to be pulled.

Multiple cables having been pulled down a row of solar arrays to be installed into their respective cable management trees. In an example, a cable management tree is deployed on the ground as an open cable tray structure, for example, every 25 feet or so running from the beginning of the solar array and then progressing down to the end of the solar array in order to secure the cables in place and in a safe manner. Next, additional operations can occur during performance of the cable installation into the cable management tree 180. The crew can start putting cables into the lowest available layer of the cable management tree 180. The crew can then put the feeder cables on the next higher elevations to stay on top of the bottom elevation feeder cables to easily install the cables as well as keep the cable management tree 180 loaded with cables stable. The crew can continue this process until each elevation/layer is seated with feeder cables in the cable clips.

The cable-pulling-rig-system can use a crimped end that is placed on each cable, allowing for a reversible connection to the hooks installed on the cable pulling jig. Once the cable is pulled to its final location and ready to be installed, the crimped ends are cut, and the cable stripped and terminated as a final installation. The cable-pulling-rig-system can focus on the installation of exposed-to-air power cabling, for example, used in the collector arrays of large solar power installations. The cable-pulling-rig-system, with slight modification to the cable management tree 180 can also be used in a host of other industries such a mining, oil and gas extraction and processing, heavy industrial, data centers and any commercial or industrial application that uses large, numerous cables installed indoors or outdoors in a structured cable management tree 180, such as an open or closed cable tray or its equivalent. The cable-pulling-rig-system significantly reduces installation time by more than 90% over existing practices. The cable-pulling-rig-system is agnostic to both the type of cable, such as a power cable, signal cable, etc., and manufacturer of cable to be pulled/installed as well as the cable tray/cable management tree 180 through which the cable is being pulled. The cable-pulling-rig-system also increases worker safety significantly by reducing physical contact with the cable and reduce the amount of weight that a craftsman is forced to lift when undertaking this type of work.

Note, circuit labeling with identifying labels is made on each feeder cable coming from its corresponding reel/cable reel. The crew can use the circuit labeling with identifying labels that comes on the cable reels of cable, to feed the cable to corresponding labeled holes in the wire guide and management jig 120. The labeled numbers correspond to the circuit/disconnect labels on the engineered drawings. Thus, the identifying labels (e.g., marked numbers) next to the holes in the wire guide and management jig 120 directly correlate to the disconnect number on engineered drawing and the circuit labeling with identifying labels on the leads of the cables. As typical, all of the cables for a particular cable tray (e.g., snake tray) are pulled together as a group of cables, the marked numbers and/or symbols used as identifying labels on the reels/cable reels of cable, wire guide and management jig 120, and cable pulling jig 140 cooperate to maintain cable logistics of an identity of each cable being pulled.

### Computing Systems

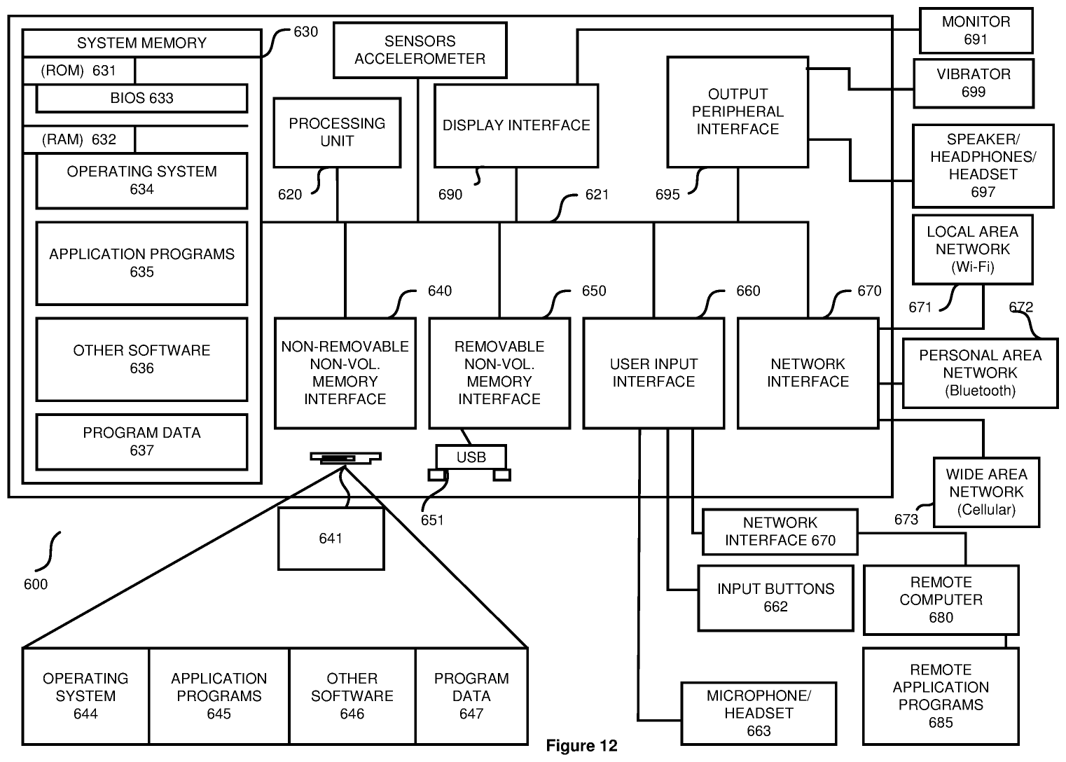

FIG. 12 illustrates an example computing device that can be implemented in one or more components discussed herein. A computing system can be, wholly or partially, part of one or more of the server or client computing devices in accordance with some embodiments. The computing systems are specifically configured and adapted to carry out the processes discussed herein. The computing device 600 may include one or more processors or processing units 620 to execute instructions, one or more memories 630-632 to store information, one or more data input components 660-663 to receive data input from a user of the computing device 600, one or more modules that include the management module, a network interface communication circuit 670 to establish a communication link to communicate with other computing devices external to the computing device, one or more sensors where an output from the sensors is used for sensing a specific triggering condition and then correspondingly generating one or more preprogrammed actions, a display screen 691 to display at least some of the information stored in the one or more memories 630-632 and other components. Note, portions of this system that are implemented in software 644, 645, 646 may be stored in the one or more memories 630-632 and are executed by the one or more processors 620.

As discussed, portions of the delivery module 10, the collection module 20, the neural networks model 30, the persistence knowledge store 40, the feedback module 50, the evaluation module 60, and other associated modules can be implemented with aspects of the computing device.

The system memory 630 includes computer storage media in the form of volatile and/or nonvolatile memory such as read-only memory (ROM) 631 and random access memory (RAM) 632. These computing machine-readable media can be any available media that can be accessed by computing system 600. By way of example, and not limitation, computing machine-readable media use includes storage of information, such as computer-readable instructions, data structures, other executable software, or other data. Computer-storage media includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other tangible medium which can be used to store the desired information and which can be accessed by the computing device 600. Transitory media such as wireless channels are not included in the machine-readable media. Communication media typically embody computer readable instructions, data structures, other executable software, or other transport mechanism and includes any information delivery media.

The system further includes a basic input/output system 633 (BIOS) containing the basic routines that help to transfer information between elements within the computing system 600, such as during start-up, is typically stored in ROM 631. RAM 632 typically contains data and/or software that are immediately accessible to and/or presently being operated on by the processing unit 620. By way of example, and not limitation, the RAM 632 can include a portion of the operating system 634, application programs 635, other executable software 636, and program data 637.

The computing system 600 can also include other removable/non-removable volatile/nonvolatile computer storage media. By way of example only, the system has a solid-state memory 641. The solid-state memory 641 is typically connected to the system bus 621 through a non-removable memory interface such as interface 640, and USB drive 651 is typically connected to the system bus 621 by a removable memory interface, such as interface 650.

A user may enter commands and information into the computing system 600 through input devices such as a keyboard, touchscreen, or software or hardware input buttons 662, a microphone 663, a pointing device and/or scrolling input component, such as a mouse, trackball or touch pad. These and other input devices are often connected to the processing unit 620 through a user input interface 660 that is coupled to the system bus 621, but can be connected by other interface and bus structures, such as a parallel port, game port, or a universal serial bus (USB). A display monitor 691 or other type of display screen device is also connected to the system bus 621 via an interface, such as a display interface 690. In addition to the monitor 691, computing devices may also include other peripheral output devices such as speakers 697, a vibrator 699, and other output devices, which may be connected through an output peripheral interface 695.

The computing system 600 can operate in a networked environment using logical connections to one or more remote computers/client devices, such as a remote computing system 680. The remote computing system 680 can a personal computer, a mobile computing device, a server, a router, a network PC, a peer device or other common network node, and typically includes many or all of the elements described above relative to the computing system 600. The logical connections can include a personal area network (PAN) 672 (e.g., Bluetooth®), a local area network (LAN) 671 (e.g., Wi-Fi), and a wide area network (WAN) 673 (e.g., cellular network), but may also include other networks such as a personal area network (e.g., Bluetooth®). Such networking environments are commonplace in offices, enterprise-wide computer networks, intranets, and the Internet. A browser application may be resonant on the computing device and stored in the memory.

When used in a LAN networking environment, the computing system 600 is connected to the LAN 671 through a network interface 670, which can be, for example, a Bluetooth® or Wi-Fi adapter. When used in a WAN networking environment (e.g., Internet), the computing system 600 typically includes some means for establishing communications over the WAN 673. With respect to mobile telecommunication technologies, for example, a radio interface, which can be internal or external, can be connected to the system bus 621 via the network interface 670, or other appropriate mechanism. In a networked environment, other software depicted relative to the computing system 600, or portions thereof, may be stored in the remote memory storage device. By way of example, and not limitation, the system has remote application programs 685 as residing on remote computing device 680. It will be appreciated that the network connections shown are examples and other means of establishing a communications link between the computing devices that may be used.

In some embodiments, software used to facilitate algorithms discussed herein can be embedded onto a non-transitory machine-readable medium. A machine-readable medium includes any mechanism that stores information in a form readable by a machine (e.g., a computer). For example, a non-transitory machine-readable medium can include read-only memory (ROM); random access memory (RAM); magnetic disk storage media; optical storage media; flash memory devices; Digital Versatile Disc (DVD's), EPROMS, EEPROMs, FLASH memory, magnetic or optical cards, or any type of media suitable for storing electronic instructions.

Note, an application described herein includes but is not limited to software applications, mobile applications, and programs that are part of an operating system application. Some portions of this description are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like. These algorithms can be written in a number of different software programming languages such as C, C+, HTTP, Java, Python, or other similar languages. Also, an algorithm can be implemented with lines of code in software, configured logic gates in software, or a combination of both. Any portions of an algorithm implemented in software can be stored in an executable format in portion of a memory and is executed by one or more processors. In an embodiment, a module can be implemented with electronic circuits, software being stored in a memory and executed by one or more processors, and any combination of both.

It should be borne in mind, however, that all of these and similar terms are to be associated with the appropriate physical quantities and are merely convenient labels applied to these quantities. Unless specifically stated otherwise as apparent from the above discussions, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers, or other such information storage, transmission or display devices.

While the foregoing design and embodiments thereof have been provided in considerable detail, it is not the intention of the applicant(s) for the design and embodiments provided herein to be limiting. Additional adaptations and/or modifications are possible, and, in broader aspects, these adaptations and/or modifications are also encompassed. Accordingly, departures may be made from the foregoing design and embodiments without departing from the scope afforded by the following claims, which scope is only limited by the claims when appropriately construed.

What is claimed is:

1. An apparatus, comprising:
a monolithic, pre-wired, pre-engineered, and pre-assembled integrated platform configured to have an electrical inverter to convert received DC power from a DC source in order to then supply AC power to an electrical grid system, where the monolithic, pre-wired, pre-engineered, and pre-assembled integrated platform also has a skeletal framework that acts as an equipment support structure for an electrical inverter, a set of electrical disconnects, electrical panels and/or cabinet enclosures, which are mounted onto the skeletal framework, where a weight of the electrical inverter, the set of electrical disconnects, and the electrical panels and/or cabinet enclosures are supported by the skeletal framework, where electrical wiring interconnecting the electrical inverter, the set of electrical disconnects, and the two or more electrical panels and/or cabinet enclosures are electrically connected up in accordance with a national electric standard in a facility, where the skeletal framework, the electrical wiring, and the electrical panels and/or cabinet enclosures are fabricated and received their respective electrical certifications in the facility as the monolithic, pre-wired, pre-engineered, and pre-assembled integrated platform prior to being shipped and installed on a construction site, where the skeletal framework supports the weight of the electrical inverter, the set of electrical disconnects, the electrical wiring, and the electrical panels and/or cabinet enclosures to allow the monolithic, pre-wired, pre-engineered, and pre-assembled integrated platform to be installed into the construction site as the monolithic, pre-wired, and pre-assembled integrated platform.

2. The apparatus of claim 1, where the DC source is a string of two or more solar power arrays that supply DC current and voltage equal to or greater than 100,000 watts into the electrical inverter, and where the electrical inverter is configured to supply the AC power out to the electrical grid system at a set frequency depending upon a standard AC frequency utilized by that country.

3. The apparatus of claim 1, where the skeletal framework has a set of legs under the skeletal framework to raise a remainder of the monolithic, pre-wired, pre-engineered, and pre-assembled integrated platform off the ground with the set of legs.

4. The apparatus of claim 1, where the skeletal framework has an upper section and a lower section with beams forming the skeletal framework, where horizontal beams are welded together with intersecting vertical beams in order to form a monolithic structure that can be lifted and carried into place as a singular modular unit, where the monolithic, pre-wired, pre-engineered, and pre-assembled integrated platform is constructed to put heavy weights of the cabinets and other equipment such that a center of gravity is essentially through a center of the platform in order to allow smooth lifting when the monolithic, pre-wired, pre-engineered, and pre-assembled integrated platform is placed in the field, where the monolithic, pre-wired, pre-engineered, and pre-assembled integrated platform has one or more structural steel stiffener plates installed between cross beams forming the skeletal framework added to a bottom of the monolithic, pre-wired, pre-engineered, and pre-assembled integrated platform.

5. The apparatus of claim 1, where a section of the skeletal framework has 1) a series of eye bolts welded into the skeletal framework, 2) reinforced holes in one or more beams making up the skeletal framework, and/or 3) a combination of both, in order to allow the monolithic, pre-wired, pre-engineered, and pre-assembled integrated platform to be lifted and set into place by at least one of a crane and a chain hoist.

6. The apparatus of claim 1, where a set of electrical panels are configured to use pre-terminated whips with at least one of male plug connectors and female receptacle electrical connectors.

7. The apparatus of claim 1, where the skeletal framework is configured to have multiple penetrations in at least one of i) a bottom floor of and ii) one or more sides of the monolithic, pre-wired, pre-engineered, and pre-assembled integrated platform to route cables internal and external to the electrical inverter, the electrical disconnects, and the electrical panels and/or cabinet enclosures mounted on the monolithic, pre-wired, pre-engineered, and pre-assembled integrated platform, where the skeletal framework, the electrical inverter, the set of electrical disconnects, and the two or more electrical panels and/or cabinet enclosures are weatherproofed for outdoors use.

8. The apparatus of claim 1, where the electrical inverter is configured to cooperate with a set of cable management trees installed in a solar array field to maintain an organization of cabling coming from each of the solar arrays when pulled and then connected up to the electrical inverter, via one or more electrical disconnects, on the monolithic, pre-wired, pre-engineered, and pre-assembled integrated platform.

9. The apparatus of claim 1, where the monolithic, pre-wired, pre-engineered, and pre-assembled integrated platform has two or more electrical inverters installed to scale up to an amount of power needed to an amount supplied to the electrical power grid by supplying enough electrical inverters, where each electrical inverter of the two or more electrical inverters is configured to be supplied from its own corresponding string of solar arrays.

10. The apparatus of claim 1, where one or more of the two or more cabinet enclosures of the monolithic, pre-wired, pre-engineered, and pre-assembled integrated platform are supervisory control and data acquisition control cabinets to allow the electrical inverter to connect and disconnect from the electrical power grid while minimizing any transient issues or other faults.

11. A method for an electrical inverter, comprising:
providing a monolithic, pre-wired, pre-engineered, and pre-assembled integrated platform configured to have an electrical inverter to convert received DC power from a DC source in order to then supply AC power to an electrical grid system, where the monolithic, pre-wired, pre-engineered, and pre-assembled integrated platform also has a skeletal framework that acts as an equipment support structure for an electrical inverter, a set of electrical disconnects, electrical panels and/or cabinet enclosures, which are mounted onto the skeletal framework, and
providing the skeletal framework to support a weight of the electrical inverter, the set of electrical disconnects, and the electrical panels and/or cabinet enclosures, where electrical wiring interconnecting the electrical inverter, the set of electrical disconnects, and the two or more electrical panels and/or cabinet enclosures are electrically connected up in accordance with a national electric standard in a facility, where the skeletal framework, the electrical wiring, and the electrical panels and/or cabinet enclosures are fabricated and received their respective electrical certifications in the facility as the monolithic, pre-wired, pre-engineered, and pre-assembled integrated platform prior to being shipped and installed on a construction site, where the skeletal framework supports the weight of the electrical inverter, the set of electrical disconnects, the electrical wiring, and the electrical panels and/or cabinet enclosures to allow the monolithic, pre-wired, pre-engineered, and pre-assembled integrated platform to be installed into the construction site as the monolithic, pre-wired, and pre-assembled integrated platform.

12. The method of claim 11, where the DC source is a string of two or more solar power arrays that supply DC current and voltage equal to or greater than 100,000 watts into the electrical inverter, and where the electrical inverter is configured to supply the AC power out to the electrical grid system at a set frequency depending upon a standard AC frequency utilized by that country.

13. The method of claim 11, further comprising:
providing the skeletal framework with a set of legs under the skeletal framework to raise a remainder of the monolithic, pre-wired, pre-engineered, and pre-assembled integrated platform off the ground with the set of legs.

14. The method of claim 11, further comprising:
providing the skeletal framework with an upper section and a lower section with beams forming the skeletal framework, where horizontal beams are welded together with intersecting vertical beams in order to form a monolithic structure that can be lifted and carried into place as a singular modular unit, where the monolithic, pre-wired, pre-engineered, and pre-assembled integrated platform is constructed to put heavy weights of the cabinets and other equipment such that a center of gravity is essentially through a center of the platform in order to allow smooth lifting when the monolithic, pre-wired, pre-engineered, and pre-assembled integrated platform is placed in the field, where the monolithic, pre-wired, pre-engineered, and pre-assembled integrated platform has one or more structural steel stiffener plates installed between cross beams forming the skeletal framework added to a bottom of the monolithic, pre-wired, pre-engineered, and pre-assembled integrated platform.

15. The method of claim 11, further comprising:
providing a section of the skeletal framework to have 1) a series of eye bolts welded into the skeletal framework, 2) reinforced holes in one or more beams making up the skeletal framework, and/or 3) a combination of both, in order to allow the monolithic, pre-wired, pre-engineered, and pre-assembled integrated platform to be lifted and set into place by at least one of a crane and a chain hoist.

16. The method of claim 11, further comprising:
providing a set of electrical panels to use pre-terminated whips with at least one of male plug connectors and female receptacle electrical connectors.

17. The method of claim 11, further comprising:
providing the skeletal framework to have multiple penetrations in at least one of i) a bottom floor of and ii) one or more sides of the monolithic, pre-wired, pre-engineered, and pre-assembled integrated platform to route cables internal and external to the electrical inverter, the electrical disconnects, and the electrical panels and/or cabinet enclosures mounted on the monolithic, pre-wired, pre-engineered, and pre-assembled integrated platform, where the skeletal framework, the electrical inverter, the set of electrical disconnects, and the two or more electrical panels and/or cabinet enclosures are weatherproofed for outdoors use.

18. The method of claim 11, further comprising:
providing the electrical inverter to cooperate with a set of cable management trees installed in a solar array field to maintain an organization of cabling coming from each of the solar arrays when pulled and then connected up to the electrical inverter, via one or more electrical disconnects, on the monolithic, pre-wired, pre-engineered, and pre-assembled integrated platform.

19. The method of claim 11, further comprising:
providing the monolithic, pre-wired, pre-engineered, and pre-assembled integrated platform with two or more electrical inverters installed to scale up to an amount of power needed to an amount supplied to the electrical power grid by supplying enough electrical inverters, where each electrical inverter of the two or more electrical inverters is configured to be supplied from its own corresponding string of solar arrays.

20. The method of claim 11, where one or more of the two or more cabinet enclosures of the monolithic, pre-wired, pre-engineered, and pre-assembled integrated platform are supervisory control and data acquisition control cabinets to allow the electrical inverter to connect and disconnect from the electrical power grid while minimizing any transient issues or other faults.
